(19) United States
(12) Patent Application Publication
(10) Pub. No.: US 2018/0213688 A1
(43) Pub. Date: Jul. 26, 2018

(54) Substrate and Carbon Fiber Laminate Generating a Low Frequency Oscillating Electromagnetic Energy Field

(71) Applicant: Edmund Coffin, Ruckersville, VA (US)

(72) Inventor: Edmund Coffin, Ruckersville, VA (US)

(21) Appl. No.: 15/877,346

(22) Filed: Jan. 22, 2018

Related U.S. Application Data
(60) Provisional application No. 62/448,716, filed on Jan. 20, 2017.

(51) Int. Cl. H05K 9/00; H01B 1/04; D06M 11/73

(52) U.S. Cl. CPC H05K 9/009; H05K 9/0088; D06M 2101/40; D06M 11/73; H01B 1/04

(57) ABSTRACT

An EM structure to emit a low frequency oscillating electromagnetic energy field has a nonpolar substrate, carbon fiber and an epoxy mixture to adhere the carbon fiber to a substrate, such as Kydex. The polarity changes from nonpolar to polar upon application of direct heat. When the EM structure is configured with two opposing sides that have the same flex modulus, the EM structure is reactive to external materials. The electromagnetic field changes the structure, or energy level, of the unprocessed material to a positive, reinforcing energy while processed foods remain in a negative, draining state.

### FIELD OF THE INVENTION

This invention relates to the creation low frequency oscillating electromagnetic energy field generated by a carbon fiber and substrate lamination r.

### BACKGROUND OF THE INVENTION

Electromagnetic fields, both from natural and man-made sources, are present everywhere in the environment. Frequency and wavelength characterize an electromagnetic field, which in an electromagnetic wave, are directly related to each other; the higher the frequency the shorter the wavelength.

Bioelectromagnetics, also known as bioelectromagnetism, is the study of the interaction between electromagnetic fields and biological entities. Areas of study include electrical or electromagnetic fields produced by living cells, tissues or organisms, including bioluminescent bacteria; for example, the cell membrane potential and the electric currents that flow in nerves and muscles, as a result of action potentials. Others include animal navigation utilizing the geomagnetic field; potential effects of man-made sources of electromagnetic fields like mobile phones; and developing new therapies to treat various conditions. The term can also refer to the ability of living cells, tissues, and organisms to produce electrical fields and the response of cells to electromagnetic fields. [Wikipedia]

Electromagnetic waves, through their electric and magnetic fields, can bring energy into a system, e.g. microwaves. Energy not absorbed or moves outward with the amount of energy absorbed being dependent upon the frequencies. Energy transfer is more efficient when the fields have the same frequency as the affected body.

The human nervous system generates electromagnetic fields, transmitting information in the form of electrical signals throughout our bodies. These signals affect nerves controlling internal functions of the body, along with our senses, muscle movement and thinking. Technical information on electromagnetic fields and the effect on bodies is replete on the web.

Medical uses of low-intensity non-ionizing electromagnetic fields have also been explored in relationship to treatment of malaria and cancer. On Oct. 2, 2014 Chemical & Engineering News, ISSN 00009-2347, published Magnetic Fields Encourage Cellular Reprogramming, Bioengineering: Adult cells revert to pluripotent stem cells more efficiently in the presence of an applied magnetic field by Katherine Bourzac. Although some skepticism was expressed by other researchers, there were enough questions raised for some researchers to feel additional research is warranted.

There are studies showing a link between low frequency oscillating electromagnetic fields, their effect on water and the resulting health benefits due to improved hydration. It is generally know that life is predominantly water. Muscles are 75%; blood 82%, lungs 90%, brain 76% and bones 25% showing that water is critical the quality of health. Dehydration affects the entire body, however the spine is especially affected as water fuels the hydraulic properties of the disc core. (Watercure by F. Batmanghelidj, M.D.). Further, according to Dr. Batmanghelidj “Fully 75 percent of the weight of the upper body is supported by the water volume that is stored in the disc core: 25 percent is supported by the fibrous materials around the disc.”

The benefits of cellular hydration are well known in the medical field as are the detriments of dehydration. Dehydration, rated as mild dehydration, less than 5% of the body's fluids; moderate dehydration, loss of 5-10% of body fluid; and severe dehydration, loss of 10-15% of body fluids which can result in a number of complications including It is believed by many that fully hydrated cells result in reduction of cell acidity, reduced autoimmune response, and increased immune system, to mention a few.

Although opinions vary regarding the cellular absorbability of plain water, it is generally agreed that fully hydrated cells are healthier than even mildly dehydrated cells. Fully hydrated cells more readily remove toxins, free radicals and generally improve cellular health.

The importance of cellular hydration is further discussed by Fisher, Dr. Howard, B.Sc., B.Ed., D.C. and Smirnov, Dr. Igor M.S., PhD. “Molecular Resonance Effect Technology: The Dynamic Effects on Human Physiology. Britannia Printers, Inc. ISBN 978-0-9780331-8-7. In this book they discuss the added benefit of water activated using Molecular Resonance Effect Technology (MRET). The device consists of pharmacologically active organic and inorganic substances that are exposed to a electromagnetic field and oscillating optical light. The frequency of the electromagnetic field is 7.8 and the light wavelength 600-700 nanometers. This exposure generates electromagnetic oscillations is similar to those found in healing waters throughout the world.

The book further states that “Consistent with the MRET theory, the applied electromagnetic field generates an excitation in the fractal geometry nano-ring of the polymer compound. Due to the phenomenon of piezoelectricity and intensive electrical activity of the fractal nano-rings, this polymer generates biologically active subtle electromagnetic oscillations. During the process of activation, the water is affected by specific patterns of subtle, low frequency, pro-biotic electromagnetic oscillations emitted by the MRET compound. The process of activation modifies the hydrogen-bonding patterns of water molecules and induces the formation of the long-range multilayer molecular structures compatible with the intercellular water structuring.”

An article published on Dr. Mercola's oneline health newsletter (mercola.com) stated that:

“Increase the structure of the water in your cells. Water is in every cell in your body, and this water is highly ordered (structured) and charged. If you don't have properly structured water in your cells, it can impact the functioning of the much larger protein molecules (and others) that interface with the cell. The water inside the cell also interfaces with water outside the cell, which has the opposite charge, creating a battery effect.

Your body's ability to generate electricity is actually a key, part of your achieving health. Electrical charges delivered from cell to cell allows for nearly instantaneous communication within your body, and the messages conducted via these electrical signals are responsible for controlling the rhythm of your heartbeat, the movement of blood around your body and much more.

In fact, most of your biological processes are electrical. The water in your cells achieves its ordered structure from energy obtained from the, environment, typically in the form of electromagnetic radiation, including sunlight and infrared heat.

But grounding may also play an important role. Just as water increases in structure when a negative charge is introduced by an electrode, the negatively charged electrons you receive when grounded help increase the structure of the water in your cells. By restructuring the water, you promote more efficient tissue healing. So, when you ground, you are charging every single cell in your body with energy your body can use for self-healing.”

As research continues there is more evidence that physiological systems are affected by electromagnetic fields that are in harmony with the electrical systems of the body.

### SUMMARY OF THE INVENTION

An EM structure to emit a low frequency oscillating electromagnetic energy field has a nonpolar substrate, carbon fiber, and an epoxy mixture to adhere the carbon fiber to a substrate, such as Kydex. The chemical make up of the substrate is such that its polarity changes from nonpolar to polar upon application of direct heat. Prior to application of direct heat the substrate is sanded in a cross hatch pattern, washed, and then dried completely. Once completely dry, the direct heat is applied, generally through flaming with the blue portion of a propane torch flame in contact with the substrate. The flaming brings the substrate temperature up to approximately 150-180 degrees F. The carbon fiber is immersed in the mixture of soft and hard epoxies until saturated and, after removal of the excess epoxy, placed on the substrate. During the application of the carbon fiber, the temperature of the substrate should not drop below 50% of the direct heat temperature and preferably no lower than 100 degrees F. The EM structure is then dried.

When the EM structure is configured with two opposing sides that have the same flex modulus, the EM structure is reactive to external materials. Materials that are unprocessed, e.g. well water, fruit, vegetables, will strengthen the structure and make the side proximate the material more difficult to flex. In contrast processed materials, such as beer, soda, foods containing chemical, when placed proximate the structure will make the side substantially easier to flex. Unprocessed foods placed proximate one side of the EM structure will not affect the flex initially but will, after about 30 minutes proximity to the structure, make the side to which it is proximate more difficult to move. The electromagnetic field changes the structure, or energy level, of the unprocessed material to a positive, reinforcing energy while processed foods remain in a negative, draining state.

### BRIEF DESCRIPTION OF THE DRAWINGS

The advantages of the instant disclosure will become more apparent when read with the specification and the drawings, wherein:

FIG. 1 shows the underside of a saddletree having carbon fiber covering, and copper wire leads in accordance with the invention;

FIG. 2 is a graph from a data logging meter of the saddletree of FIG. 1 in accordance with the invention;

FIG. 3 shows the underside of a saddletree having carbon fiber covering and copper wire leads with a second field in proximity to the wire leads in accordance with the invention;

FIG. 4 is a graph from a data logging meter of the saddletree of FIG. 2 showing the change in the electromagnetic field upon introduction of a second field in accordance with the invention;

FIG. 5 is a graph representing the electromagnetic field when placed on a horse in accordance with the invention;

FIG. 6 is a graph representing the electromagnetic field when placed on a horse in accordance with the invention;

FIG. 7 is a top view of a bicycle seat sized EM structure in accordance with the invention;

FIG. 8 is a comparison table showing the median heart rate, over a period of time, for a horse ridden in different saddles; and

FIG. 9 is graph of median heart rates illustrated in FIG. 8.

### DETAILED DESCRIPTION OF THE INVENTION

### Definitions

For the purposes as employed herein the term “aquaporin” shall refer to the integral membrane proteins that form pores in the membrane of biological cells, mainly facilitating transport of water between cells. (Wickipedia) In 2003, the Nobel Prize for Chemistry was awarded for the explanation of how ‘Aquaporins’(the cells water channels) carry water, one molecule at a time through the cell membranes.

For the purposes as employed herein, the term “base output” shall refer millivolt output by the disclosed EM structure without external influence by an object or human presence.

For the purposes as employed herein, the term “affected output” shall refer millivolt output by the disclosed EM structure with external influence by an object or human presence.

For the purposes as employed herein the term “electromagnetic” shall refer to the interrelation of electric currents or fields and magnetic fields.

For the purposes as employed herein the term “electromagnetic field” shall refer to a field of force that consists of both electric and magnetic components, resulting from the motion of an electric charge and containing a definite amount of electromagnetic energy.

For the purposes as employed herein the term “electromagnetic induction” shall refer to the production of an electromotive force (i.e., voltage) across an electrical conductor due to its dynamic interaction with a magnetic field.

For the purposes as employed herein, the term “substrate” shall refer to a material, natural or synthetic, that is used as the base or body of the object and that, in combination with the method disclosed herein, produces electromagnetic fields. The substrate used is manufactured from Kydex, a mixture of polyvinyl chloride, chlorinated polyvinyl chloride, acrylic polymer, as well as a mixture of processing aids, impact modifiers, heat stabilizers and lubricants and an organotin compound. The organotin compound and processing aid, impact modifier, heat stabilizer, lubricant and pigments mixtures are proprietary to Sekisui SPI and protected as trade secrets. Kydex further has stain resistant properties. Other substrate materials can be used, however they must have the characteristics of Kydex to produce optimum results. Due to the number of elements within the Kydex and the proprietary information of some ingredients, it is unknown whether the substitution of another material will produce the same results.

For the purposes as employed herein the term “EM structure” shall refer to a substrate that has been prepared in accordance with the disclosure hereinafter, including the carbon fiber and epoxy and that emits a low frequency, oscillating electromagnetic energy field.

For the purposes as employed herein the term “flex” shall mean to bend by expansion of one surface and contraction of the opposing surface.

For the purposes as employed herein the term “Flex modulus” shall refer to the physical property denoting the ability for a material to bend. An increased or strengthened flex modulus refers to a decrease in flex (or an increased resistance to flex). A decreased or weakened flex modulus refers to an increase in flex (or a decreased resistance to flex).

For the purposes as employed herein, the term “epoxy” shall refer to any adhesive, soft or hard, applicable to use with the chosen composite and substrate. These include various solid or semisolid amorphous fusible natural organic substances as well as any of a large class of synthetic products that have some of the physical properties natural adhesives but are different chemically and are used chiefly in plastics.

For the purposes as employed herein, the term “soft epoxy” shall refer to any adhesive applicable for use with the chosen substrate that has an elasticity of about 150,000 PSI thereby being more flexible than standard epoxies while stiffer than adhesive sealants. The softer epoxy should have the ability to make structural bonds that can absorb the stress of expansion, contraction, shock, and vibration. It is ideal for bonding dissimilar materials.

For the purposes as employed herein, the term “hard epoxy” shall refer to any adhesive applicable for use with the chosen substrate that has strong physical properties for structural bonding.

For the purposes as employed herein, the term “polar” refers to a material having molecules with a positive electrical charge on one side and a negative electrical charge on the other side. [thoughtco.com]

For the purposes as employed herein, the term “magnetic field homogeneity” refers to a uniform electric field which has the same strength and direction at each point.

For the purposes as employed herein, the term “non polar” refers to a material having molecules which have no separation of charge, so no positive or negative poles are formed. In other words, the electrical charges of nonpolar molecules are evenly distributed across the molecule. Nonpolar molecules tend to dissolve well in nonpolar solvents, which are frequently organic solvents. [thoughtco.com]

For the purposes as employed herein, the term “saddle tree” shall mean the frame of a saddle onto which all additional materials are secured and forms the basic manner in which the saddle contacts the horse and rider.

The applicant has a long history of working to improve saddle trees to optimize the comfort for a horse as well as the connection between a horse and rider, Further, the applicant trains and evaluates performance horses for their owners as well as owns a number of horses. Through the work to design and manufacture the optimal saddle, it was found that with a new manufacturing process changes were noted in horses both when being saddled in preparation for being ridden and when being exercised in the saddle. The first change was that the horses all exhibited a greater sense of relaxation. Next was noted significant reduction, or elimination of back pain in a 20-30 minute period just while standing. In the Fall of 2015, the applicant began an initiative to have all test horses wear saddles at rest for at least 40 minutes per day, 7 days per week for the purpose of exploring the long term benefits of the electromagnetic field generated by the saddle. Soon thereafter, another physiological change was noted; improved cardiovascular functioning, including lower resting heart rate and recovery after exercise when using a saddle having the tree manufactured in the disclosed manner, attributable to a great extent to hydration. Then over time greater health benefits on a broad spectrum of physiological functions were noted. These benefits included improved digestion, food utilization, elimination of digestive disorders, improved lymphatic circulation, elimination of generic swelling, improved immune system, reduction or elimination of allergies and notable improvements to hydration levels. As the common denominator of these physiological is water, the hypothesis was the electromagnetic field was somehow creating improved levels of intracellular water.

Horses in training that were switched from, prior art saddles to the saddles containing the saddle tree disclosed herein showed a marked improvement in movement and a lessening of resistance to being saddled. They demonstrated improved balance, less resistance to riders' requests, longer strides, improved straightness and ability to bend in either direction, better carriage and improved jumping style.

Seeking an explanation of the favorable reaction by the horses, it was found that some saddle trees did not flex the symmetrically after periods of use. This was discovered as there was an immediate and precipitous decline in the performance of test horses, sometimes even when wearing a saddle at rest. Upon close examination, small surface anomalies were discovered that, when eliminated, restored the symmetrical flexion. These anomalies were always of a certain nature, always relating to the consistency of the carbon fiber surface and consistent in their effect on proper flexion. When the saddles were returned to symmetrical flexion, the performance of the test horses, even at rest, was immediately restored. It was hypothesized that a current or energy flow was occurring on the saddle tree surface and that surface anomalies were disrupting the flow. This disruption in the energy flow was triggering a negative response from horses. It was then discovered that deliberately caused anomalies could have predictable consequences on the symmetry of saddle flexibility and horse response. In the many thousands of test conducted over the course of several years, this relationship between surface anomalies, asymmetry of flexion and negative horse response has been completely consistent.

Since the original configuration was a saddletree, the further experiments were also conducted using the prepared saddle trees. This was not only for the consistency of the test model but for the ability to easily flex the saddle tree. As disclosed hereinafter a partial tree, the size of a bicycle seat, was also used for testing, however due to the absence of panels, it was difficult to test the degree of flex. The size reduction did however provide that the field existed in other configurations and that the size of the field is directly related to the size of the EM structure. For example, a saddletree emits a field approximately six foot while an EM structure the size of a bicycle seat emits a field approximately 3 feet, extending in all directions forming a cube. There is no known reason why the electromagnetic field would not work on a flat EM structure the same as it does on the curved saddletree.

### Materials

The substrate used is a nonpolar material that does not have normal bonding processes and requires special preparation to adhere the carbon fiber. It is believed that the process required to prepare the substrate for adhesion is integral to the creation of the electromagnetic field.

The substrate is initially prepped by sanding with 150-220 grit in a cross hatched pattern. This pattern etches the surface and increases the mechanical bond between the substrate and carbon fiber. Although the sanding does not need to be absolutely perfect, any areas not sanded are subject to delamination.

Once sanded the substrate is washed and placed in a heating element producing dry heat at 120 degrees. The substrate is a porous material and absorbs moisture during the washing process. In order to provide adherence, the substrate must be moisture free. The amount of time required to dry the substrate is dependent upon the thickness and size. For example a ⅜ inch thick substrate would be dried in a heating element for about 12 hours while a ⅛ inch thick substrate would be dried for approximately 6 hours. Ambient drying is possible but timing is dependent upon the current weather conditions.

Once dry, a propane torch is then run over the entire surface sufficient close to produce a blue flame on the surface. This is a critical step as the flaming changes the polarity of the substrate. During the flaming, the temperature is raised to about 160 to 180 degrees and the surface ionized, thereby trading electrons and changing the polarity. Care must be taken not to burn or melt the substrate while still raising the temperature to the degree where the polarity is changed.

As the substrate does not hold heat, the epoxy saturated carbon fiber must begin to be applied with one or two minutes, Therefore it is preferable that the carbon fiber be prepared and waiting at the time of commencing the flaming. During, the carbon fiber application process the substrate should not fall much below 100 degrees or at most 50% of the post flaming temperature. In order to successfully avoid an undesired drop in temperature and to avoid delamination, all materials, including air, equipment, chemicals and surfaces must be maintained at between 70-80 degrees. A dedicated room maintained at the desired temperature and containing all components is recommended to prevent delamination.

The resin preparation used to adhere the carbon fiber to the substrate is a mixture of hard and soft epoxies. An example of a hard epoxy would be West Systems 105/205 mix or the equivalent. West Systems' G/flex two part adhesive, or its equivalent, is used as the soft epoxy. A mixture is formed of 1 part hard epoxy and 1 parts soft epoxy. Can be altered depending on end use and desired flex, difference.

The carbon fiber is placed within the epoxy mixture until it reaches the point of complete saturation, the point at which no more epoxy can be absorbed. At this point it is squeegeed to remove excess epoxy and then placed on the still hot substrate. When the EM substrate is a saddle tree, it is placed on the underside of the tree.

The coated substrate is baked at 105 degrees to cure for approximately 4 hours. Alternatively, the substrate can be left at room temperature for curing, with the time difference between baking and ambient curing being based on the room temperature.

The result of the foregoing process produces an EM structure having piezo electric, phenomena producing low frequency oscillating electromagnetic properties in the 7.8 range, closely aligned with the levels naturally produced by the human body. As explained by Lipkova, J. and Cechak, J in “Human electromagnetic emission in the ELF band”. Measurement Science Review, Volume 5, Section 2, 2005. Further “EEG has shown that waves do not expand to the brain only, but through the whole nervous system (through the perineural system) to every part of the organism.” Although at high levels, such as microwaves, electromagnetic waves are dangers, when aligned with the waves naturally produced by the body. they can provide a number of benefits.

### Testing Example I

### Discovery of Millivolts and Electromagnetic Field

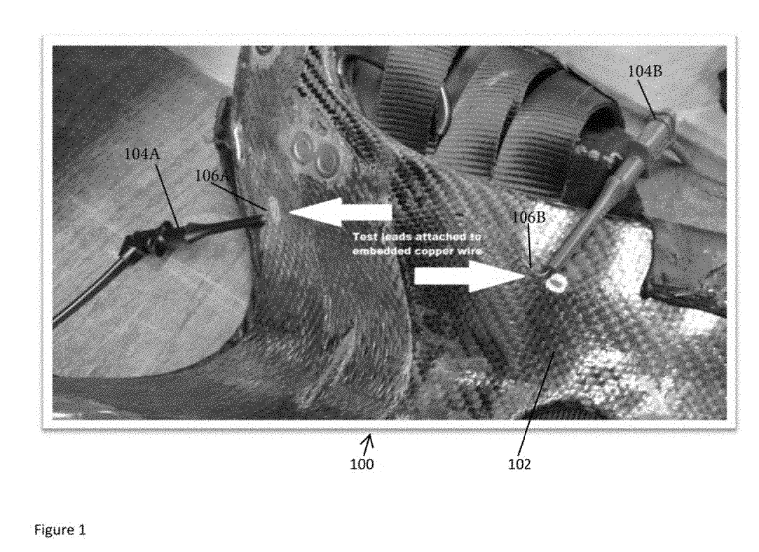

In FIG. 1 the underside of a substrate with an adhesive resin/carbon fiber 102 coated saddletree 100 is illustrated. The saddletree 100 has two (2) layers of adhesive resin coated carbon fiber 102 covering the substrate. Copper wires 106A and 106B have been placed within the resin/carbon fiber 102 without coming into contact with the substrate. Test probes, negative probe 104A and positive probe 104B are then attached to the copper wires 106A and 106B. The test probes 104A and 104B are connected to a data logging meter, such as a multimeter.

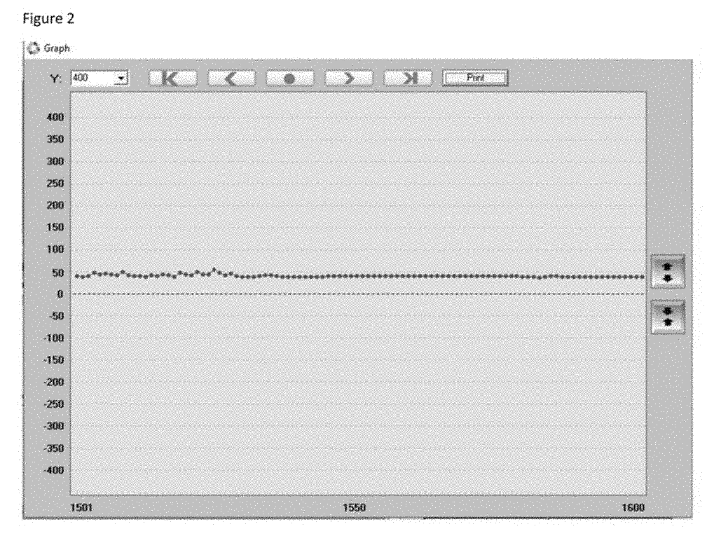

Readings from the probes 104A and 104B, as received from the copper wires 106A and 106B, are read by the data logging meter. The graph of FIG. 2 shows the reading from the data logging meter with data points at one second intervals, providing a baseline millivolt reading of 50.

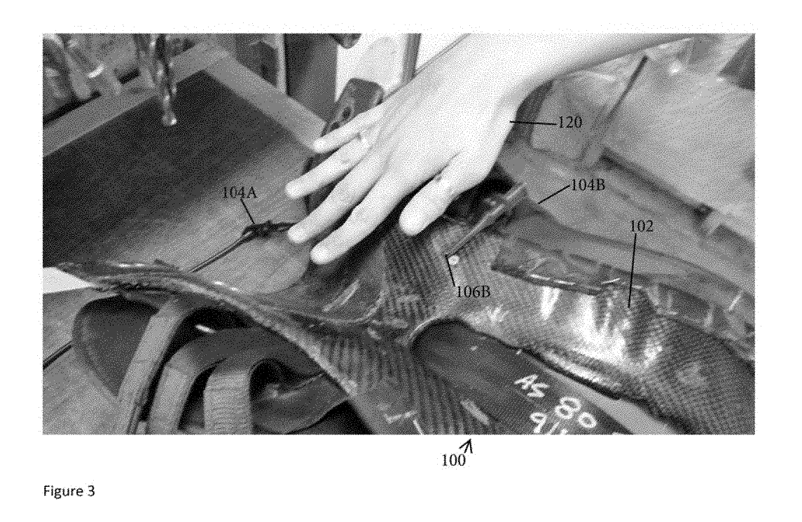

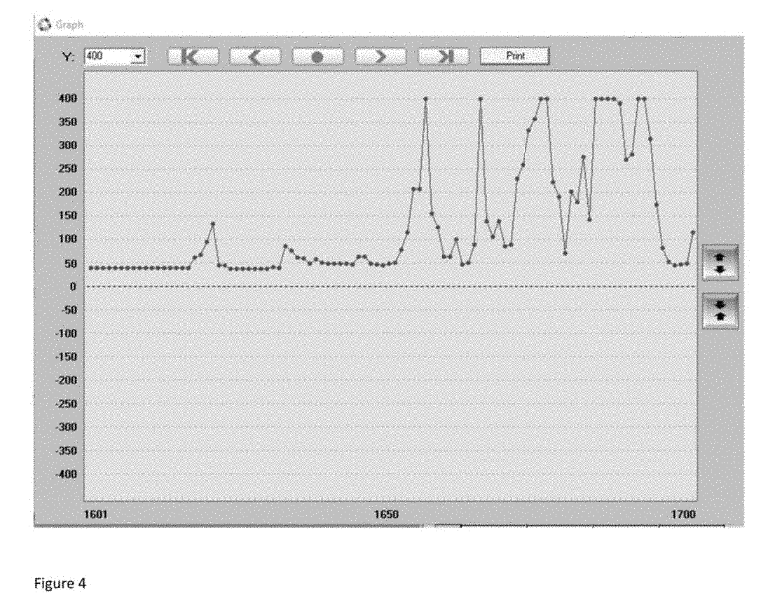

Without moving the probes, a second field 120 (in this illustration a hand) is introduced proximate to, but not touching, the carbon fiber 102 as illustrated in FIG. 3. The graph of FIG. 4 illustrates the data points as the source of the second field 120 is moved around the saddletree 100. As can be seen from the graph of FIG. 4, the baseline reading of 50 increases to 400 as the second field approaches and drops back to 50 as the second field is removed. Moving the second field closer and further from the saddletree raises and lowers the millivolt readings.

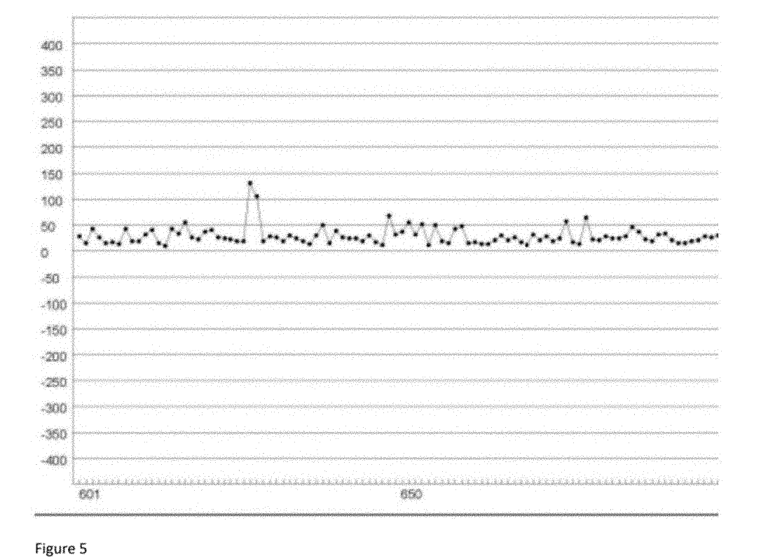

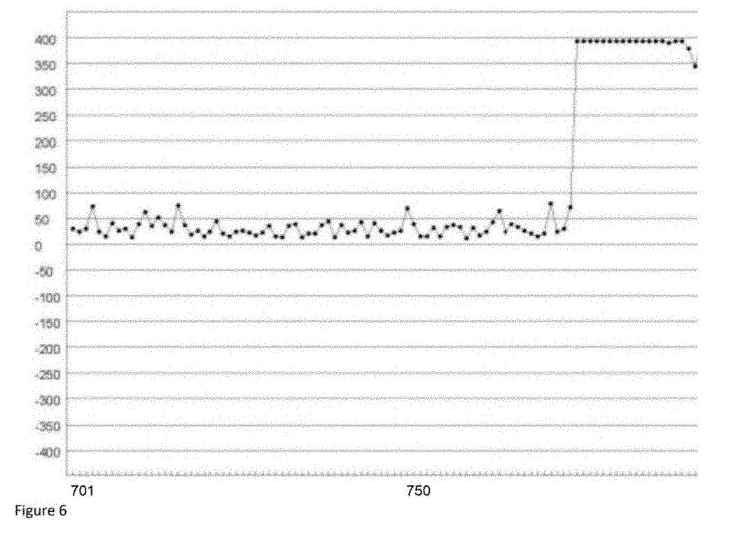

In FIGS. 5 and 6 the graph represents the millivolt differences when a saddle, made with the saddle tree disclosed herein, has been placed onto a horse at rest. There are regular and recurring oscillations in the milivolt readings, suggesting ongoing exchange of energy between the horse and the saddle tree,

### Testing Example 2

### Effects on Equine Physiological Systems

The saddles were used consistently on a daily basis for 1-2 hrs/day. Horses were housed in applicant's facilities with two of the horses recovered from Cushing's, and one having allergies. With continued use of the saddle as stated, the horses with Cushing's recovered and the allergies were eliminated.

The horses were under strict control and receive no medications, dietary supplements, or therapies, and no change in diet. All elements were tightly controlled, with the same riders, same amount of exercise, and the only variable being the saddle. A positive effect was seen on a broad spectrum of biological systems including nervous system, pain, cardiovascular, digestive and lymphatic systems. Multiple saddles were used in the testing, eliminating the possibility that the negative effects stemmed from a single poor fitting saddle.

The nervous system showed the first effect of exposure in that the normally agitated response to being saddled changed. Horses become measurably calmer as demonstrated by less movement, fidgeting, less tail ringing, biting, pawing.

The next observed effect of the saddletree was pain. Back pain, common in horses, is checked by palpation along the horse's spine. During palpation horse flinches or pulls away or in extreme cases partially collapses. On the tested horses having a demonstratively sore back a normal saddle left on and at rest for 20-30 min exacerbates the back pain. The disclosed saddle, left on and at rest for 20-30 min completely or nearly completely alleviates the back pain.

The reduction in pain was also noted in how the horses moved during exercise. Leg stiffness due to join pain was eliminated and carriage improved.

Cardiovascular improvement, determined by heart rate, was vastly improved an is described in more detail below.

Digestive systems were improved evidenced in a virtually elimination of diarrhea, disappearance of allergies and improved coats.

The lymphatic system showed improvement through the lack of edema associated with horses their age.

Hydration suspected to be the primary cause of the majority of improvements. In the test subjects hydration increased without extra water while recovery time after exercise was reduced.

### Test Example 3

### Improved Equine Cardiovascular Functioning

### Background

The following study of three saddles was undertaken based on expansion of an existing model used by the designer/manufacturer of the Tad Coffin saddles. Two saddle models were utilized, the A5 and the TC2, both close contact saddles designed for use in hunter/jumpers. In the data attached these saddles are referred to with the symbols TC. The third saddle was a Steuben, all-purpose saddle with a deeper seat, originally purchased for the fit of the tree, then classified by the manufacturer as a narrow tree.

Based on the designers preliminary data on equine heart rate while wearing the TC saddles, a small study was made comparing resting heart rates between the two saddle types. The horse was ridden in one or the other saddle for a 30 minute period. This procedure was followed for a minimum of 5 consecutive days for each saddle.

### Subject and Materials

Horse—15 year-old thoroughbred gelding; 17 hands, with typically prominent withers; show hunter; sound cardiovascular, respiratory and musculoskeletal systems prior to and throughout the experiment.

Observer/experimenter—Horse's regular rider, a retired equine veterinarian with background in physiology and pharmacology specific to anesthesia, trained and certified in animal chiropractic with several years of practical experience in this discipline with the horse.

### Saddles

### Tad Coffin Performance Saddle A5 and TC2

A Steuben all-purpose saddle with narrow tree width selected from a number of saddles for this particular horse. This saddle is the observers normal, everyday saddle.

Girth—Professionals Choice nylon backed with neoprene panel, elasticized on both buckle ends (this horse's everyday girth)

Padding—Standard, contoured cotton quilt under pad and a Mattes fleece half pad (this horse's usual padding)

### Experiment

Melissa Holland DVM performed the following testing at her barn. Heart rate (HR) was measured by digital palpation of the left facial artery as it crosses the medial surface of the mandible. The study was begun each day in the horse's stall. The horse was not tied or cross tied at any time but allowed to move freely around the stall. The horse was groomed as usual in preparation for the day's ride. Heart rate was measured, noted as elapsed time zero (0) in the attached data, and then the saddle was applied and positioned as normal for this horse. The girth was applied so that a finger was easily slipped between the horse's rib cage and the girth. Heart rate was measured by a vet thereafter every 5 minutes and recorded for a total of 20 mutes. Heartrate was measured by placing a finger under the jaw bone and timing the heartrate with a stopwatch.

The horse was then ridden for a total of thirty (30) minutes. For the first 10 minutes, the horse was allowed to walk on a loose rein with contact gradually taken for the latter half of this warm up period. The last 20 minutes consisted of trotting and cantering. Occasionally low verticals were jumped. At the end of the 20 minutes, the rider brought the horse to a walk, dismounted immediately and took the first heart rate measurement. This point is noted as elapsed time 50 minutes in the data chart and table attached. At elapsed time 52 minutes, 55 minutes, 60 minutes, etc., the heart rate was measured. At approximately elapsed time 55 minutes, the saddle was removed. At approximately elapsed time 60 minutes, the horse was given a bath with tepid water to assist cooling (as usual post-work for this horse during warm weather). Heart rate was measured for a minimum of 60 minutes after the end of the horse's work (last measurement at elapsed time 110 minutes).

Data was gathered over a period of five riding days for the Steuben saddle and eight (8) riding days for the Tad Coffin (TC) saddles. The median heart rate for each elapsed time period from 0 to 110 minutes was compared, as illustrated in FIGS. 9 and 9.

### Results

As can be seen in the table above and following graph, the horse's median resting heart rate was consistently 36 bpm at time zero. The application of both the TC2 and the A5 saddles produced a significant reduction in heart rate. The heart rate dropped approximately 30% by the first reading at 5 minutes after saddle application and remained at this level throughout the 20 minute pre-ride period. The Steuben saddle produced no change in heart rate pre-ride.

Return to resting heart rate, 36 bpm for this horse, occurred on average, within 3 minutes post ride for the Tad Coffin saddles. For the Steuben saddle, 11.7 minutes was required for return to the horse's resting heart rate. Interestingly, the horse's heart rate continued to drop below the resting rate for the Tad Coffin saddles and consistently stabilized at the pre-ride-with-saddle-on rate of 28 bpm. The rate remained at this level for at least one hour (60 minutes) post ride. This phenomenon did not occur with the Steuben saddle.

### Other Observations

This experiment began by determining the effect on heart rate, if any, between either the Tad Coffin A5 or TC2 and the Steuben saddle. The Tad Coffin saddles produced a significant reduction in heart rate and this effect was prolonged. This suggests that repetitions of this study should provide that the order of saddle placement should be such that the Tad Coffin saddle is the second saddle tested. In other words, apply the non-Tad Coffin saddle first to reduce the possibility that the horse's resting heart rate will be inaccurate.

The effect on the horse's heart rate recovery produced by variations in ambient temperature and humidity could not be isolated in this study. Nor could the influence of respiration be easily correlated with changes in heartrate. Respiratory rate post exercise was elevated, and even more so as humidity, in particular, climbed. These findings would be expected intuitively, but there was no consistent correlation with heart rate. Post exercise cooling was assisted by hosing with tepid, not cold, water. The application of water to the skin areas supplied by the great veins of the neck and legs and then to the entire skin surface is a common method used to speed cooling in horses post exercise as is application of circulating air, usually supplied with fans. Fans were not used for cooling in this study.

In general, the horse was alert during work, though he seemed almost sedated in the stall. This is a quiet individual under most circumstances, so this latter observation may have nothing to do with the effect of a saddle. Interesting side note: this horse does not love horse showing. He seemed much less ‘worried’ about the whole horse show experience after riding in the TC A5 each day.

Measurements and trends with the two Tad Coffin saddles were fundamentally similar. The TC2 was first evaluated. The rider returned to the Steuben and measured heart rate for 5 rides. Then measurements were made with the A5 saddle. Riding in and out of these saddles at these weekly intervals was subjectively interesting. The horse's way of going in the TC saddle seemed to ‘hang over’ into the time spent riding in the Steuben (say around 4 rides). Once returned to the second TC saddle, the A5,there was a period of about 2 days when the horse seemed to be ‘testing or experimenting’ with the saddle change. Again, on about ride number 4, he settled back into the TC frame and way of going (difficult to describe other than to say better balanced and more efficient self-carriage in all gaits; the sense that the rider must remember not to over-ride. Communication is more efficient?)

### Suggestions for Further Study

The mechanism for the heart rate changes and differences in recovery to resting heart rate post exercise produced by the Tad Coffin saddles is unknown. The recovery to resting heart rate after exercise was significantly faster with the Tad Coffin saddles (median 3 minutes) than with the Steuben saddle (median 11.7 minutes). Even more curious is the initial drop in heart rate produced by the Coffin saddles pre-exercise and the persistent lower than resting heart rate eventually reached post-exercise.

Further monitoring of the post-exercise heart rate would be helpful. On two occasions where measurements were made, the heart rate remained at this level for at least two hours post exercise in the TC saddle. This effect was also evident at competition (horse show). The heart and heart rate recovery results were similar to those observed ‘at home’.

Levels of the stress hormone Cortisol will need to be test as. both heart rate and cortisol levels are affected by the balance between sympathetic and parasympathetic nervous system function. Sympathetic is the fight or flight system. Heart rate goes up. Parasympathetic acts as a counterweight to the sympathetic system. Heart rate comes down. One could measure levels of resting cortisol and heart rate in the horse in the pre-exercise condition. Measure resting cortisol and heart rate, then after 20 minutes in the non-TC saddle, measure again. Repeat for several days. Then do the same experiment for the TC saddle. Does the heart rate decrease with the TC saddle correspond with a change in blood cortisol levels? This might be a tricky study to do. Baseline blood cortisol levels would have to be well documented in the study subjects such that any changes which accompanied the application of a saddle would be measurable without too much artifact In order to minimize the effect of outside influence on the horse's cortisol levels, observers would most appropriately be the subject horse's regular rider and the horse should be in a familiar environment with regular routine.

Based on the results of the study described herein, other studies that would be of interest include:

A study comparing effect on heart rate by saddles where the saddle design/manufacturer is unknown to the observer and where the saddles are substantially similar in appearance

A study measuring heart rate while stimulating acupuncture points along the bladder meridian where saddles typically are positioned on the horse's back.

### Summary

The effect on heart rate produced by saddles designed by Tad Coffin (TC) Performance Saddles and a Steuben saddle was measured in a fit, 15 year old thoroughbred gelding both at rest and after 30 minutes of exercise at the walk, trot and canter. The TC saddles produced a 30% reduction in heart rate at rest and a return to resting heart rate (36 bpm) post, exercise in significantly less time—3 minutes for the TC saddles vs. 11.7 minutes for the Steuben saddle. Further reduction in heart rate below resting level post-exercise was produced by the TC saddles, but not by the Steuben saddle. Application of the Steuben saddle did not produce a reduction in heart rate at rest nor did this saddle produce a post-exercise reduction in heart rate below resting heart rate.

### Notes on the Table and Chart

The accompanying chart has a gap between elapsed time 20 minutes, and 50 minutes. This gap corresponds to the 30 minutes of riding where measurements could not be taken. The first measurement is at the end of the ride. The total elapsed time at this point is 50 minutes.

The pale green dot just above 35 on the heart rate axis is the resting heart rate pre saddle application with each saddle. This horse's resting heart rate of 36 bpm is consistent from day to day. The heart rate decrease to 28 bpm with the TC saddles is noted by the red boxes. Heart rate in bpm for the Steuben measurements is represented by the purple X's.

Heart rate measurements for each time point in the table are the median rates in bpm for the 5 days spent riding in the Steuben saddle (ST) and 8 total days in either the TC2 or the A5.

Further studies on structures larger and smaller than a saddletree should be conducted to verify that identical results are produced. Further, the test subjects should be expanded. To date most studies have been on equines with only antidotal input from people. User input has been a noticed reduction in back pain, increase in hydration, muscle function. All of the antidotal input to date appears to be directed to an increase in hydration by providing the cells with a greater access to the balanced water.

### Testing Example 4

### Electromagnetic Field in the Saddle Tree and its Effect on Water

The electromagnetic field of the saddle tree has a definitive effect on water. The hypothesis is that water exposed to the field is somehow restructured or reconfigured. This appears to be the case for intracellular and extracellular water. This would explain the improvements in hydration levels and the associated health benefits that have been observed with test horses consistently using the saddle.

While testing is insufficient at this point to definitively support this hypothesis there are previously cited studies that support the concept of, restructured water and its benefits.

If a quantity of bottled or well water is placed alongside a saddle tree of the disclosed description and the saddle tree is then flex tested for symmetry, the presence of water has no impact on the manner in which the tree flexes. If the quantity of water is left within the saddle trees' electromagnetic field for approximately 30 minutes and the saddle tree is retested for symmetry, the side on which the water is positioned will be significantly stiffer and resistant to flex given the same force applied to it. The opposite side will flex normally. The hypothesis is that the exposure to the electromagnetic field has reconfigured the water structure. When placed on one side of the saddle tree, it seems to create a positive imbalance within the energy field. When placed either directly in front of or directly behind the saddle tree on the longitudinal axis, the symmetry is unaffected. This additionally supports the idea of the presence of an energy field.

In addition, the water has been widely observed to have a smoother texture and little to no aftertaste.

This same test can be conducted with fruits and vegetables with significant water content. If initially placed alongside the saddle tree and the saddle tree is flexed, it will flex symmetrically. If left in the electromagnetic field for 30 minutes and the saddle is retested for symmetry, the side on which the item is placed has an impact of the flexibility of the saddle tree consistent with that of the water mentioned above.

Water that has been treated with chemicals or that has had refined sugars or salts added will cause the saddle, upon initial presentation alongside the saddle tree, to flex asymmetrically. This asymmetry is characterized by a weakening of resistance when force is applied When left in the electromagnetic field for approximately 30 minutes, the water will not be reconfigured and subsequent flex tests will continue to show a weakened response to force along the side on which it is placed. The hypothesis is that the added substances create a negative imbalance in the energy field.

### Test Example 5

### Changing the Flex Modulus of a Structure by Creating a Positive or Negative Imbalance in the Energy Field

There is a relationship between the flex modulus of a structure of the disclosed description and the positive or negative imbalance of the energy field. This relationship is not well understood but the patterns of response in test environments are completely consistent. Thus a structure can be manipulated to respond differently to forces acting upon it, depending on whether the field was balanced or not and if not then whether the imbalance was positive or negative.

Tests have demonstrated that certain substances cause a negative imbalance in the energy field. This weakening allows a greater flex modulus and increased mobility when forces act upon the structure. These items are typically ones that contained highly processed additives or chemicals. Examples of these items are certain adhesives, refined sugars and salts, food preservatives as well as chemicals and many common pharmaceuticals.

Testing has also demonstrated that certain items create a positive imbalance in the energy field and cause a stiffening or reduction of mobility. These substances are typically unrefined and naturally occurring. Examples include organic raw sugar, Himalayan salt and reconfigured water.

Utilizing this phenomena to create variations in a structures' response to forces acting upon it could prove quite useful. An example of this could be a pair of wings constructed according the disclosed description. Conceivably the manipulation of wing shape could be altered to create a change of course.

The uses are extensive and could produce remarkable results. For example

Restructure water consumed as well as restructuring water within the body's cellular structure.

### General Observations

In addition to the effect the electromagnetic wave on physiological systems, the EM structure can also influence the way other structures flex by strengthening or weakening electromagnetic field.

In order to determine additional information on the effect of an anomaly on the flex of a saddle, standard adhesive tape was used to provide the obstruction to the electromagnetic field.

In the initial tests a small length of tape, approximately 2″, was placed with an edge along the centerline of the saddle at which point the side of the saddle containing the tape did not flex as readily as the opposite side. Upon turning the tape 90 degrees, the other side of the saddle flexed.

To test the extent of the electromagnetic field a 3 inch piece of clear adhesive tape was placed on a small piece of wood, sticky side up. The tape was adhered to the wood by folding under the ends. When placed to be perpendicular to the saddle on one side, the opposing side flexes. The wood/tape combination were moved away from the saddle a couple inches at a time until there was no reaction as far as flex. It was found that the field extended five (5) to six (6) feed from the pommel; six (6) to eight (8) feet from the cantle and three (3) to four (4) feet from the sides.

Other potential uses for the EM structure.

Air plane wings containing an electromagnetic field generated as disclosed could have the flex affected, to change lift or course alteration.

A test method to determine whether an item or a food is harmful to humans and animals. For example placing an cell phone on one side of a testing EM structure to see if the flex modulus is affected.

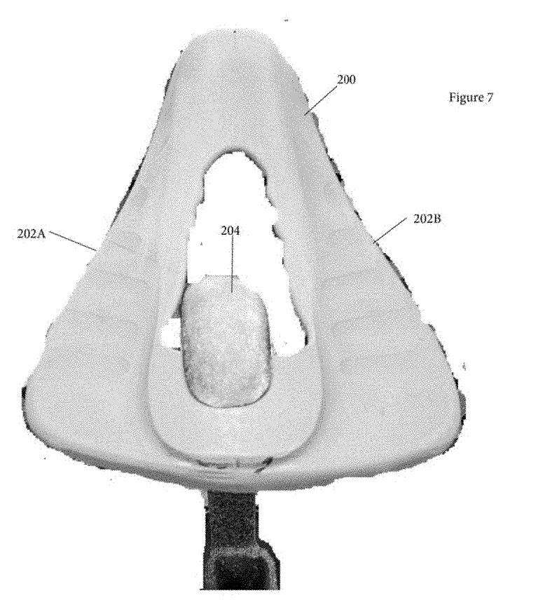

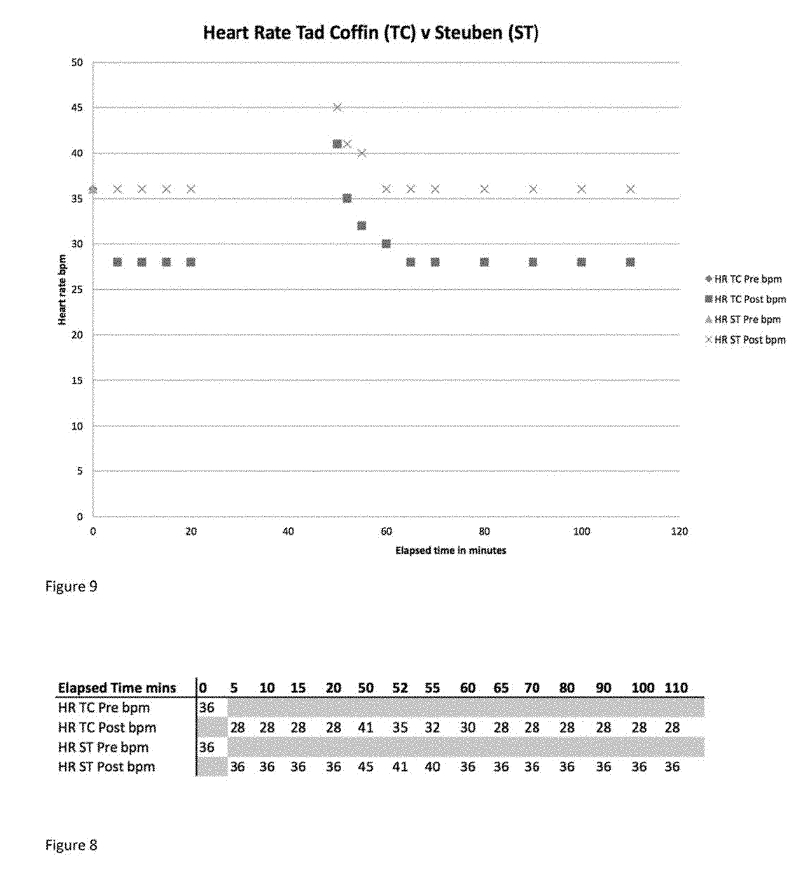

In FIG. 7 a saddletree, prepared as described heretofore, has been cut to approximately the size of a bicycle seat to form EM structure 200. The EM structure 200 has been clamped to more easily measure the electromagnetic field. As can be seen in this figure, the sides 202A and 202B do not have sufficient length to flex as with the saddletree. In order to test whether this configuration still produced an electromagnetic field a glass of water next to the EM structure 200 and left for 20 min. The water was then put it next to the EM structure in the form of a saddletree at which time the flex modulus was affect and the side proximate the water would not flex. This was repeated with the glass of water being, moved systematically further from the EM structure 200. The effect of the electromagnetic field of the EM structure was strongest close to the saddle and diminished as the water was moved further away. The effect was relatively consistent up until about 3 feet and rapidly diminished thereafter. The maximum effective distance was about 4 feet.

When the surface of the saddletree is asymmetrical, e.g., tape or other interference placed on the surface, there is a change in the readings. When the surface of the carbon fiber is unobstructed, symmetric induction occurs; however once the symmetry is broken, induction will not occur.

The electromagnet field affects the flex modulus of the saddle. Without any anomaly or obstruction to the saddle, such as unevenness in the carbon fiber, the flex of the saddle is equal on both sides. Once there is an anomaly, the flex is unequal.

There is a marked decreased resistance to flex in the proximity of heavily processed foods, such as soda or beer. Further, depending on the degree of processing, these foods apparently do not absorb the electromagnetic energy and continue to “draw” from the EM structure, never increasing the resistance to flex. One test included Maca powder which should have increased the flex resistance but rather decreased the resistance. Further inspection of the product, in small print, disclosed that it contained a chemical known to cause birth defects.

Further, organic foods, even those with low or no water content affect the flex modulus. For example, Himalayan salt and organic sugar strengthen the flex modulus while iodized salt and refined sugar weaken the flex.

One possibility for this occurrence is that the energy created by the electromagnetic energy field seeks a current balance between the items within the field. Therefore an item placed next to a saddletree generating a field would either draw from the generated field or support the field. Once an item has a current equal to the saddletree it reflects back the current, reinforcing the saddletree and making that side extremely difficult to flex. Movement of the item from one side to the other of the saddletree causes the flex modulus to reverse sides.

It is believed that the effects of the electromagnetic field directly taps into the biological system's pain relief response, directly affecting the mitochondria. Having an EM structure close to food and drink appears to enhance the water within, making it more absorbable and usable by the body possibly through the change of the hydrogen bonds. The probably restructuring of the water, based on research as noted above, seem to be having a direct effect on intracellular hydration.

The health benefits from exposure to low frequency, oscillating electromagnetic fields, as discussed heretofore, is known however there is little research into the exact nature of this energy. From the results seen, and discussed hereinafter, the electromagnetic field produced by the disclosed EM substrate are similar to those areas considered to be geomagnetic anomalies, such as Sedona, Ariz.

### Broad Scope of the Invention

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims (e.g., including that to be later added) are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language of the present invention or inventions should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure, the following abbreviated terminology may be employed: “e.g.” which means “for example.”

What is claimed is:

1. An EM structure to emit a low frequency oscillating electromagnetic energy field comprising:
a nonpolar substrate, said substrate changing from nonpolar to polar upon application of direct heat to bring said substrate to a first predetermined temperature,
carbon fiber, said carbon fiber being applied to said substrate prior to reaching a second predetermined temperature, and
epoxy, said epoxy adhering said carbon fiber to said substrate.

2. The EM structure of claim 1 wherein said first predetermined temperature is between 160 and 180 degrees F.

3. The EM structure of claim 1 wherein said carbon fiber is soaked in said epoxy to saturation and excess epoxy removed prior to placement on said substrate.

4. The EM structure of claim 1 wherein said second predetermined temperature is greater than 100 degrees F.

5. The EM structure of claim 1 wherein said second predetermined temperature is greater than 50% of said first predetermined temperature.

6. The EM structure of claim 1 wherein said substrate is sanded in a crosshatch pattern and then washed and dried prior to application of said direct heat.

7. The EM structure of claim 1 wherein said direct heat is a propane torch at a distance to enable a blue portion of a flame to contact said substrate.

8. The EM structure of claim 1 wherein said epoxy is a mixture of soft epoxy and hard epoxy.

9. The EM structure of claim 1 wherein said substrate is Kydex.

10. The EM structure of claim 1 wherein said EM structure has opposing flexible sides, each of said opposing flexible sides having an equal flex modulus.

11. The EM structure of claim 10 wherein said flex modulus of each of said opposing flexible sides is increased or decreased depending upon a material placed proximate one of said opposing flexible sides.

12. An EM structure for the emission of low frequency oscillating electromagnetic energy field comprising:
a nonpolar Kydex substrate, said substrate changing from nonpolar to polar upon application of direct heat to bring said substrate to a temperature of between 160 and 180 degrees F.,
epoxy, said epoxy being a mixture of hard epoxy and soft epoxy,
carbon fiber, said carbon fiber being applied soaked in said epoxy, excess epoxy removed and applied to said substrate prior to reaching a temperature no less than 80 degrees F.

13. The EM structure of claim 12 wherein said substrate is sanded in a crosshatch pattern and then washed and dried prior to application of said direct heat.

14. The EM structure of claim 12 wherein said direct heat is a propane torch at a distance to enable a blue portion of a flame to contact said substrate.

15. The method of creating an EM structure for the emission of electromagnetic currents comprising the steps of:
a. Thermoforming a substrate into a predetermined configuration,
b. Sanding said substrate in a cross hatched pattern,
c. Washing said substrate,
d. Drying said substrate,
e. Flaming said substrate to bring a temperature to about 160 to 180 degrees F.,
f. Soaking carbon fiber in an epoxy mixture of hard epoxy and soft epoxy
g. Removing excess epoxy mixture from said carbon fiber
h. Apply said carbon fiber to said substrate
i. Drying said substrate carbon fiber structure to form an EM structure;
wherein said EM structure emits a low frequency, oscillating electromagnetic energy field surrounding said EM structure.

16. The method of claim 15 further comprising the step of forming said EM structure to have opposing flexible sides, each of said opposing flexible sides having an equal flex modulus.

17. The method of claim 16 further comprising the step wherein placing a material proximate one of said opposing flexible sides affects said flex modulus of said one of said opposing sides.

18. The method of claim 16 wherein said material is a first material containing water and is unprocessed and said flex modulus of said one of said opposing flexible sides is increased making said one of said opposing flexible sides more difficult to flex.

19. The method of claim 16 wherein said material is a second material containing water and is processed and said flex modulus of said one of said opposing flexible sides is decreased making said one of said opposing flexible sides easier to flex.

20. The method of claim 16 wherein said material is a third material containing water and is unprocessed and said flex modulus of said one of said opposing flexible sides is unaffected for a predetermined period of time and after said predetermined period of time said one of said opposing flexible sides is more difficult to flex.
